(19) United States
(12) Patent Application Publication
(10) Pub. No.: US 2007/0121007 A1
(43) Pub. Date: May 31, 2007

(54) VIDEO SIGNAL SAMPLING SYSTEM WITH SAMPLING CLOCK ADJUSTMENT

(76) Inventor: Markus Waldner, Klagenfurt (AT)

Correspondence Address: O'Shea, Getz & Kosakowski, P.C.;Suite 912, 1500 Main Street, Springfield, MA, 01115, US

(21) Appl. No.: 11/561,725

(22) Filed: Nov. 20, 2006

(30) Foreign Application Priority Data
Nov. 18, 2005 (DE) 10 2005 055 543.8

(51) Int. Cl. H03L 7/00

(52) U.S. Cl. 348/537

(57) ABSTRACT

A video signal sampling system comprises an analog-to-digital converter that samples an analog video signal under the control of a sampling clock signal to provide a digital video signal. A processor processes the digital video signal by computing at least two derivatives of the digital video signal in order to provide a phase correction signal value. A delay locked loop receives the phase correction signal value and a clock signal, and adjusts the phase of the clock signal based upon the phase correction signal value to provide the sampling clock signal.

### PRIORITY INFORMATION

This patent application claims priority from German patent application 10 2005 055 543.8 filed Nov. 18, 2005, which is hereby incorporated by reference.

### BACKGROUND INFORMATION

The invention relates to video signal processing, and in particular to adjusting the sampling instant of a sampling clock in a video signal sampling system.

An analog video signal is supplied from a video signal source and sampled by a sampling clock that has a fixed sampling frequency. The sampling clock is obtained by a temporal shift from a base clock having a fixed base clock frequency. The required shift is determined from the video data by a regulation procedure and typically a phase-coupled delay loop. Such video data obtained by sampling are provided for further processing.

An ideal sampling instant for an analog signal—supplied by, for example, a graphics card in a computer—is located at the site where the individual pixels have their plateau in the signal. In order to prevent so-called clock jitter from becoming visible in an image represented by the digital data, the plateau during sampling should be hit at the midpoint as precisely as possible. The problematic aspect here is that the transitions from one pixel to the next are relatively narrow and thus difficult to detect. If, when the analog signal is sampled, the pixels are hit in the transitions rather than the plateau, the image becomes quite blurred, and in the case of fine image structures moiré patterns can be detected which are caused by the clock jitter.

Statistical methods, among other approaches, are typically used to regulate the sampling instants of a sampling clock as precisely as possible towards the midpoint. However, a disadvantageous aspect of statistical methods is that, by their very nature, they are quite slow since they always require and must process a large amount of data. Reconstructing and regulating the phase position of a sampling clock with respect to an analog signal to be sampled according to DE 10 2004 027 093 is disadvantageous because an analog circuit element is required that supplies information on a signal gradient for the sampling instant, with the result that it is not possible to employ a conventional analog-to-digital converter (ADC).

There is a need for a technique of adjusting the sampling instants of a sampling clock in a video signal sampling system for the purpose of supplying a digital video signal from an analog video signal, preferably with reduced circuit complexity and low computational cost.

### SUMMARY OF THE INVENTION

An analog video signal is sampled by a sampling clock with a sampling frequency to supply digital video data, and the sampling clock is temporally shifted from a base clock for sampling. The amount of shift is determined from the video data, where a sequence of amplitude differences is determined between respectively at least two amplitude values of the video data, a minimum sampling instant is determined as the instant with the least amplitude difference out of the sequence of amplitude differences, and the sampling instants to be used for sampling are determined from the minimum sampling instant plus an shift quantity not equal to zero.

A value between ⅓ and ⅔ of a period of the sampling frequency may be employed as the value of the a shift quantity. For example, a value of approximately ½ of a period of the sampling frequency may be employed as the value of the shift quantity.

An averaging of adjacent amplitude differences is implemented to determine the minimum sampling instant. The shift is determined such that the sampling instants of the sampling clock fall within a plateau region of a pixel. The video data are filtered before determining the minimum sampling instant, for example, using a median filter and a low-pass filter. The sampling frequency is equal to a video frequency or equal to an even-numbered or integer multiple of a video frequency.

The amplitude differences are generated from respectively two immediately successive amplitude values of the video data. A plurality of successive amplitude differences are summed. The amplitude differences of at least one line (e.g., a line of an image) are summed and compared with the summed values of the same line from another image.

A method in which a Δ function is generated by acquiring the first difference value as a first Δ function value, and by shifting the sampling clock and acquiring another difference value as another Δ function value, and in which the minimum sampling instant is determined—alternatively or additionally—indirectly from a minimum of the Δ function. The minimum sampling instant is determined—alternatively or additionally—indirectly by determining a maximum of a second derivative of the Δ function, where the Δ function is generated from successive amplitude differences.

A circuit comprising an analog-to-digital converter (ADC), a clock source to supply a base clock, and a regulating device that receives the base clock and supplies and regulates a sampling clock for the ADC converter.

Advantageously, no statistical procedures are required. In addition, information about a signal gradient is not required, with the result that, the system of the present invention is less expensive. What is solved in particular is a problem encountered in PC applications) and in general with applications in which an analog signal coming from a graphics card must be sampled. To ensure that a sharp image can be generated by the digitized video data, the individual pixels must be hit as precisely as possible at the midpoint during sampling of the analog signal.

A sampling goal is to precisely hit the pixel transitions between two pixels since these yield an unambiguous value. Since the pixel period is known, during a second step the found phase position can subsequently be used to generate the ideal sampling instant by shifting, preferably by half a pixel period. What is exploited here is that in a subtraction of successive sampling values a difference minimum situated in the region of pixel transitions can be located especially precisely. In addition, the pixel transitions that are simple to find by this procedure are offset by half an image period relative to the ideal sampling instants in the midpoint of the pixel plateau.

These and other objects, features and advantages of the present invention will become more apparent in light of the following detailed description of preferred embodiments thereof, as illustrated in the accompanying drawings.

### BRIEF DESCRIPTION OF THE DRAWINGS

FIG. 1 is a block diagram illustration of a video signal sampling system;

FIG. 2 is a block diagram illustration of a video signal sampling system;

FIGS. 3A-3C illustrate three examples of a sinusoidal oscillation sampled at different phase positions, respectively;

FIG. 4 illustrates a typical analog video signal to be sampled;

FIGS. 5A-5B illustrate the amplitude values of an input signal, as well as values of a Δ function generated therefrom;

FIGS. 6A-6C illustrate a signal with noise and measurement errors, and the values filtered therefrom;

FIGS. 7A-7C illustrate a first and second derivative of a sequence of data accumulated as a Δ function; and

FIGS. 8A-8E illustrate another signal sequence and signal characteristics for intermediate processing steps.

### DETAILED DESCRIPTION OF THE INVENTION

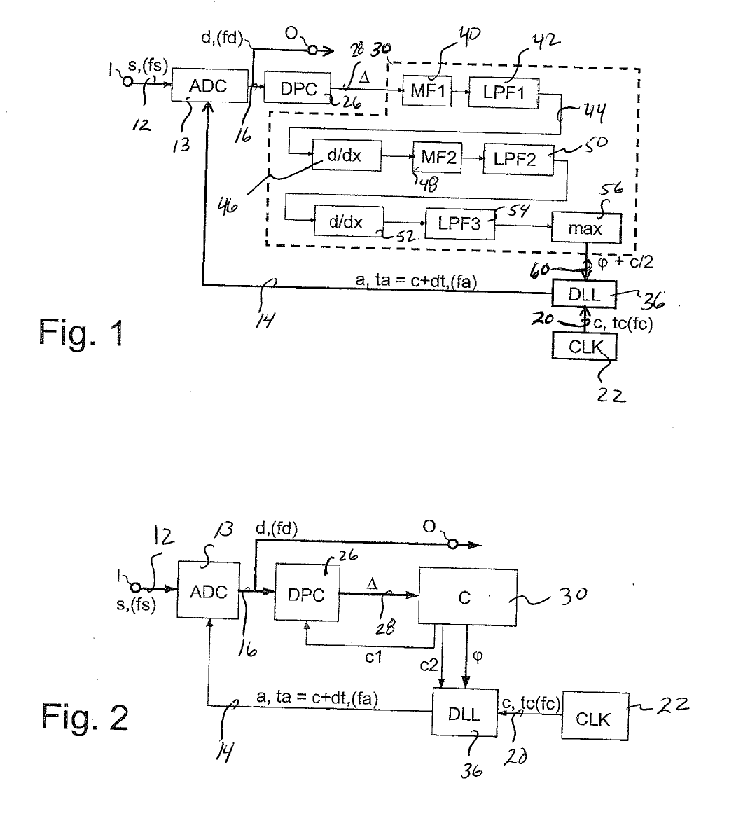

Referring to FIG. 1, an analog video signal is input on a line 12 to an analog-to-digital (ADC) 13 that samples the analog video signal at discrete sampling instants ta of a sampling clock a on a line 14 and outputs digital video data d on a line 16. The digital video data d preferably have a video data frequency fd with double the frequency of a base clock frequency (fc) of a base clock signal on a line 20 supplied by a clock source 22.

The digital video data are input to a data phase control device 26 forming an intelligent sensor that implements the described measurements. Referring to FIGS. 1 and 2, the data phase control device 26 generates a Δ signal on a line 28 that is applied, for example, to a control device 30 (e.g., a processor). In addition to control signals c1, c2 on lines 32, 34 that are applied to the data phase control device 26 and a phase control device 36, the control device 30 also determines a phase shift for the purpose of transmitting a required correction phase or a desired phase φ that is applied to the phase control device 36. The phase control device 36 preferably includes a delay locked loop (DLL) and generates the sampling clock a on the line 14 from the base clock c on the line 20.

Amplitude differences for successive sampling values or digital video data values are determined and summed to supply the Δ signal on the line 28 from a sequence of successive and summed difference values. These accumulated or summed values are fed to a first median filter 40 and then to a first low-pass filter 42. The values thus filtered are applied on a line 44 to a derivative device 46 to generate the first derivative dΔ/dx of the Δ function. The values thus derived are applied to a second median filter 48 and then to a second low-pass filter 50, before another derivative is generated in a corresponding derivative device 52. The doubly derived values of the Δ function are applied to a third low-pass filter 54, and, after low pass filtering, search logic 56 identifies a maximum value in the sequence of the thus-supplied data values.

The instant of the maximum value is supplied as a phase value φ on a line 60, to which the value of a half period c/2 of the sampling clock a or of the base clock c is added, to effect the phase correction of the sampling clock. What is exploited here is the fact that the maximum value of the doubly derived Δ function corresponds to a minimum value of the Δ function itself, or to a minimum value of the sequence of amplitude differences between successive sampling values or digital video data d. The shift by a half period c/2 of the base clock c occurs since the thus determined value corresponds temporally to a transition instant midway between two pixels. The shift of the sampling clock a is appropriately effected relative to the horizontal synchronization pulse.

The ADC 13 and the data phase control device 26, as well as the control device 30, are in the form of individual hardware or hardware combined in one component. On the other hand, the filter and derivatives are preferably implemented through software executing within the control device 30.

FIGS. 3A-3C illustrate three examples of a sinusoidal oscillation sampled at the same sampling clock a in the form of an exemplary analog video signal s, where each of the sinusoidal oscillations is sampled at different phase positions. What are examined are the amplitude differences Δ1, Δ2, Δ3 between two respective successive sampling points ta1, ta2, ta3, ta4. What is evident is that the amplitude differences Δ1, Δ2, Δ3 become increasingly larger the further the sampling points ta1, ta2, ta3, ta4 are removed from the inflection point of the function of the sinusoidal oscillation. This information is employed to select the sampling instant.

The sampling frequency fa is preferably double the signal frequency fs of the analog video signal s, or digital data derived therefrom as indicated by fa=2*fs. This fact is actually in contradiction to the sampling theorem with the condition fa>2*fs, whereby it is precisely because of this that the most ideal adjustment possible of the sampling instant is required.

The sinusoidal functions can be represented graphically by a checkerboard pattern with alternating black and white pixels, where the maximum amplitude has the value white, the minimum amplitude has the value black, and all amplitudes midway between these have the value gray. It is evident in FIGS. 3A and 3B, that a corresponding gray image would be displayed, and that only in FIG. 3C would a black-and-white pattern be displayed.

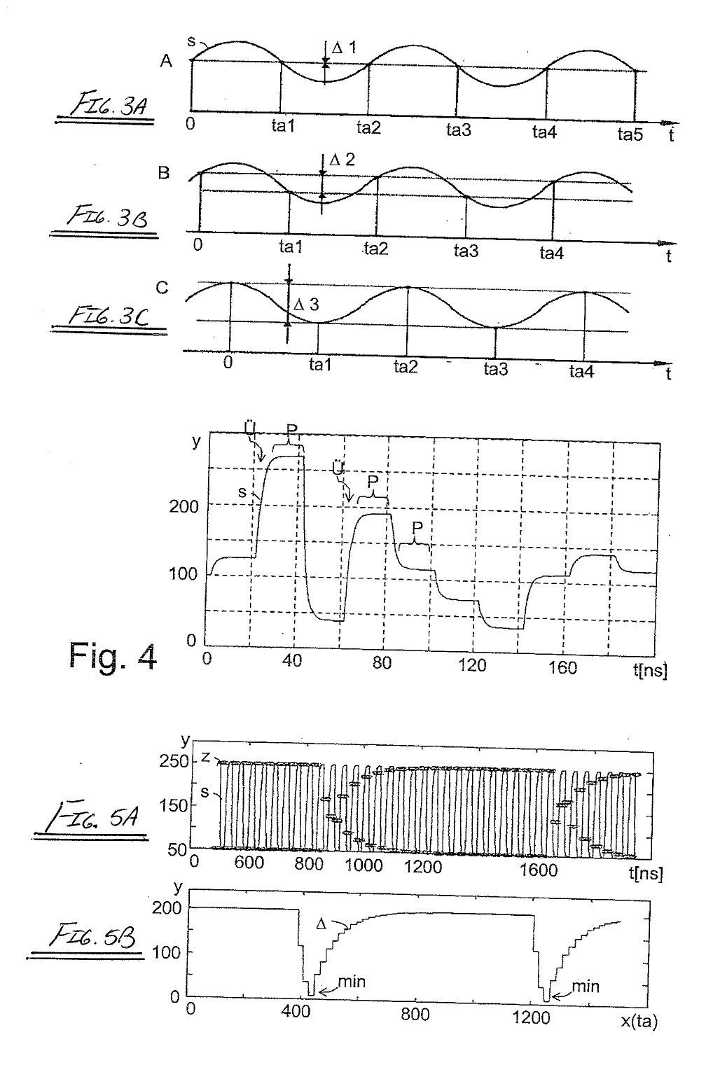

The system of the present invention identifies the phase position at which amplitude differences Δ3 are the greatest. However, the technique begins initially with a first reverse step: that is, what is searched is the phase position at which the amplitude differences are at their smallest—as illustrated in FIGS. 4 and 5.

FIG. 4 illustrates a typical analog video signal s plotted against the time axis t, as supplied by a graphics card (not shown). This analog video signal s does not look like a sine function, but instead like a charging and discharging curve familiar in the case of, for example, capacitors. The analog video signal s has a plateau P that is quite broad and has by comparison a narrower transition region Ü. If, now, what were searched were the maximum of the pixel amplitude differences, similar results would be obtained over a wide range. The result would not be unambiguous. The cost incurred from nevertheless obtaining a stable result would be relatively high. On the other hand, it is surprisingly efficient to find the minimum of the amplitude differences. This fact provides the advantage that it supplies an unambiguous result, as is evident from FIGS. 5A and 5B. FIG. 5A illustrates values y of sampling values z for the analog video signal s plotted against time axis t. In the case of the exemplary black-and-white display, these values would again only be displayed as gray.

FIG. 5B illustrates the corresponding absolute data values y of a delta function Δ as a function of the time axis t shifted by 400 ns. In the case of the exemplary black-and-white display, a checkerboard pattern would again be displayed, as would a delta function Δ ultimately generated therefrom if the sampling instant is gradually shifted. The minima of delta function Δ are clearly seen.

According to a preferred technique for adjusting the sampling instants ta, it is possible to start from an arbitrary position. In other words, the sampling clock a driving the ADC is located at an arbitrary phase position for the analog video signal s. Subsequently, all the differences located, in the form of amplitude differences, in a given line of a to-be-sampled image are summed. The amplitude difference is thus generated for two successive sampling values z and added to the previous sum of differences. This procedure has the advantage of being less sensitive to noise and measurement errors. The procedure is based on the assumption that the sum of averaged smaller differences is less than the sum of averaged larger differences.

In order nevertheless to obtain a quick result, it is preferably not an entire to-be-sampled image that is examined but rather only a representative line thereof. Evaluation of the lines and the selection of an appropriate line is implemented by an intelligent sensor in the form of the data phase control device 26 (FIGS. 1 and 2) which can also be a component of a higher-level control device. The data phase control device 26 preferably ensures that within the subsequent sequence it is always the same line that is measured so as to have a reference.

Once the first value of the Δ function has been obtained, an image, subsequently sampling clock a, is shifted by a certain phase quantity dt. This shift is implemented, for example, by the regulating device 36. As a result, discrete phase values can be readily adjusted. After measurement of the line, a second function value of the delta function Δ is obtained. This process is preferably continued until the sampling clock a has been shifted through an entire pixel period. During the complete measurement, it is determined at which site or at which phase position the minimum min of the delta function Δ is located.

Since the pixel period and the sampling period (1/fa=1/fc) are the same, and the sampling clock a is typically known, the sampling clock a can be shifted such that it is offset by exactly half a period c/2 or a/2 relative to the delta function minimum, and as a result the ideal sampling instant ta has been adjusted.

Since changes in the image content and measurement errors may occur during the measurement, the minimum is preferably searched by an approach illustrated in FIG. 1 and FIG. 6A-6C. FIGS. 6A-6C illustrate accumulated values y of three such delta functions Δ plotted for sampling instants ta or for a sequence of sampling values x. In FIG. 6A the delta function Δ is error-free, while in FIG. 6B the delta function Δ is affected by noise and measurement errors. The low-pass filter 42 and the median filter 40 are used to attenuate the noise and eliminate measurement errors. The delta function Δf illustrated in FIG. 6C is accordingly filtered. In this example, the noise is represented in exaggerated form since it is already an integrated function. Nevertheless, the minima min can be determined precisely.

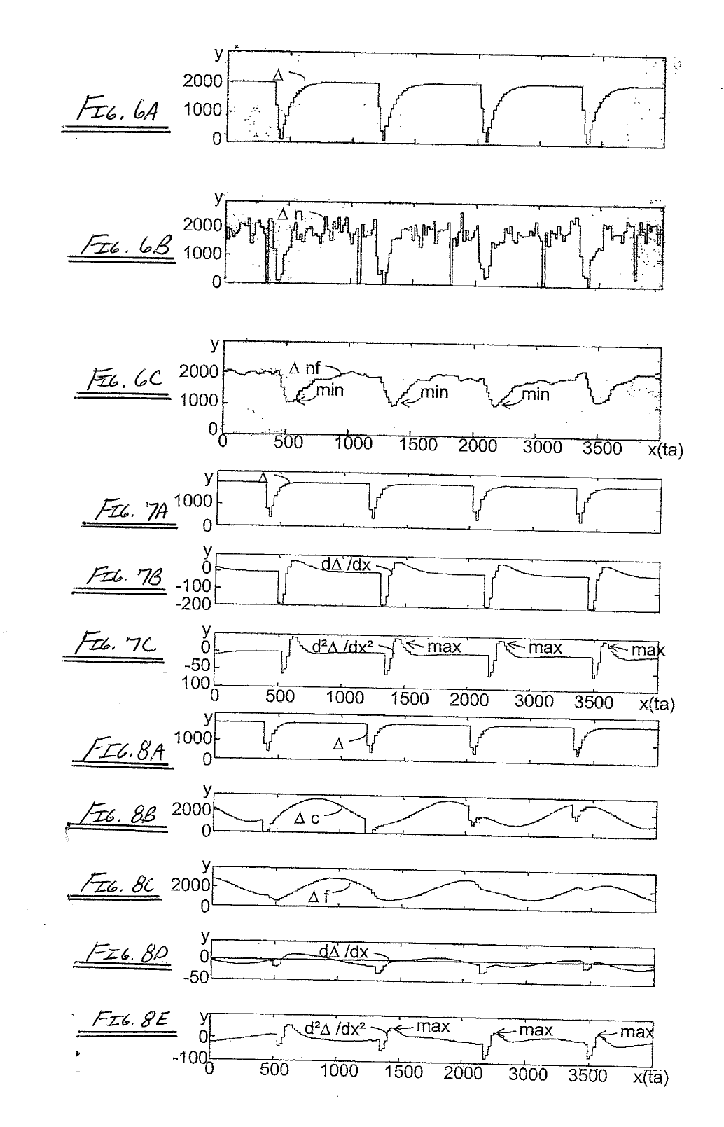

A more complex problem arises when the image content changes. In this case, the form of the delta function Δ changes. In order nevertheless to make a determination about where the minima min are located, the delta function is derived twice, as is illustrated in FIGS. 1, 7A-7C, and 8A-8E. Plotted in FIGS. 7A-7C are accumulated values y of three delta functions Δ for the sampling instants ta or the sequence of the sampling values x, where FIG. 6B corresponds to the first derivative, while FIG. 6C corresponds to the second derivative. FIGS. 8A-8E analogously shows, from top to bottom, an undisturbed delta function Δ, a delta function Δc with changing contrast during the measurement, a filtered delta function Δf, a delta function dΔ/dx with the first-order derivative, and a delta function d²Δ/dx with the second-order derivative, respectively.

The maximum value max of the second derivative is located at the site where minimum value min of the original function is located. However, in this derived function the disturbing signal components have dropped out. As is evident from FIGS. 8A-8E, maxima max of the second derivative can be precisely assigned to minima min of the delta function Δ. The shift results from the computational process, is static, and can be compensated.

Although the present invention has been illustrated and described with respect to several preferred embodiments thereof, various changes, omissions and additions to the form and detail thereof, may be made therein, without departing from the spirit and scope of the invention.

What is claimed is:

1. A method for adjusting sampling instants of a sampling clock in a video signal sampling system, comprising:
sampling an analog video signal, under the control of a sampling clock signal, to provide a digital video signal;
temporally shifting a base clock signal a variable amount as a function of the video data to generate the sampling clock signal;
where the variable amount is determined by
determining a sequence of amplitude differences between at least two amplitude values of the video data;
determining a minimum sampling instant as the instant of the least amplitude difference from the sequence of the amplitude difference; and
determining the variable amount from the minimum sampling instant plus a shift quantity not equal to zero.

2. The method of claim 1, where a value between ⅓ and ⅔ of a period of the sampling frequency is used as the value of the variable amount.

3. The method of claim 1, where a value of approximately ½ of a period is the value of the variable amount.

4. The method of claim 1, where the step of determining of the minimum sampling instant comprises averaging of adjacent amplitude differences.

5. The method of claim 1, where the variable amount is determined such that the sampling instants of the sampling clock fall within a plateau region of a pixel.

6. The method of claim 1, comprising filtering the video data prior to the step of determining the minimum sampling instant.

7. The method of claim 1, where the sampling frequency value is equal to a video frequency or an even-numbered integer multiple of the video frequency.

8. The method of claim 1, in which the amplitude differences are generated from two immediately successive amplitude values of the video data.

9. The method of claim 8, where a plurality of successive amplitude differences is summed.

10. The method of claim 9, where the amplitude differences of a line of an image are summed and compared with summed values from the same line of another image.

11. The method of claim 1, where a Δ function is generated by acquiring a first difference value as the first Δ function value, and by shifting the sampling clock and acquiring another difference value as another Δ function value, and in which the minimum sampling instant is determined, alternatively or additionally, indirectly from a minimum of the Δ function.

12. The method of claim 11, comprising determining the minimum sampling instant by determining a maximum of a second derivative of the Δ function, wherein the Δ function is generated from successive amplitude differences.

13. A video signal sampling system, comprising:
an analog-to-digital converter that samples an analog video signal under the control of a sampling clock signal to provide a digital video signal;
means for processing the digital video signal by computing at least two derivatives of the digital video signal in order to provide a phase correction signal value;
a phase control device that receives the phase correction signal value and a base clock signal, and adjusts the phase of the base clock signal based upon the phase correction signal value to provide the sampling clock signal.

14. The system of claim 13, where the means for processing comprises a processor.

15. The system of claim 13, where the means for processing comprises:
a cascaded median filter and low pass filter.

16. The system of claim 13, where the phase control device comprises a delay locked loop.

17. A video signal sampling system, comprising:
an analog-to-digital converter that samples an analog video signal under the control of a sampling clock signal to provide a digital video signal;
a processor that processing the digital video signal by computing at least two derivatives of the digital video signal in order to provide a phase correction signal value;
a delay locked loop that receives the phase correction signal value and a clock signal, and adjusts the phase of the clock signal based upon the phase correction signal value to provide the sampling clock signal.
